(19) United States
(12) Patent Application Publication
(10) Pub. No.: US 2008/0142953 A1
(43) Pub. Date: Jun. 19, 2008

(54) SEMICONDUCTOR DEVICE

(75) Inventor: Harumi MIZUNASHI, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 11/955,668

(22) Filed: Dec. 13, 2007

(30) Foreign Application Priority Data
Dec. 14, 2006 (JP) 2006-337486

(51) Int. Cl. H01L 23/02

(52) U.S. Cl. 257/704; 257/E23.19

(57) ABSTRACT

With a conventional semiconductor device, there occurs deterioration in adhesion strength of bonded parts between a lid and a substrate. A semiconductor device according to an embodiment of the invention includes a substrate, a semiconductor chip with one of surfaces thereof, facing downward, mounted on the substrate, and a lid having a depressed part for accommodating the semiconductor chip, and a flange linked with the depressed part. Parts of the flange of the lid are bonded to the substrate by means of a binder. The flange is warped arcuately against the substrate, as seen in a side view. The bottom surface of the depressed part of the lid is bonded to the other surface of the semiconductor chip by means of a binder.

### FIELD OF THE INVENTION

The present invention relates to a semiconductor device.

### BACKGROUND OF THE INVENTION

Enhancement in working speed of a high-performance semiconductor device available lately has been accompanied by an increase in heating value thereof. In order to cope with such a trend, a technology called flip chip mounting has been put to use in a semiconductor package (hereinafter referred to as a package) with increasing frequency.

FIG. 7 is a sectional view showing a conventional semiconductor device using the flip chip mounting. With this semiconductor device, use is made of a method whereby electrode terminals of a semiconductor chip 105 are positioned opposite to electrode terminals of a substrate 103, respectively, so as to be bonded with each other through the intermediary of bumps 107 formed on the tops of the respective electrode terminals of the semiconductor chip 105. External terminals 104 are connected to the underside surface of the substrate 103. With the adoption of this method, it is possible to enhance a working speed because the respective electrode terminals of the semiconductor chip 105 can be connected with the respective electrode terminals of the substrate 103 with an interval interposed therebetween being at the shortest. Further, since the package does not have a substrate provided on the back surface side of the semiconductor chip 105, this method has an advantage in that a lid 101 corresponding to a heating value of the package can be installed. Further, as a constituent material of each of the bumps 107, use is often made of a tin-lead alloy, tin-silver alloy, tin-silver-copper alloy, gold-tin alloy, and so forth.

The lid 101 has a depressed part provided at the central area thereof, for accommodating the semiconductor chip 105, and a flange 101a provided on the outer periphery thereof. The lid 101 of such a construction as described may be particularly referred to as a cap-type lid. The cap-type lid is described in, for example, JP-A 2001-210761. The back surface of the semiconductor chip 105 is bonded to the bottom surface of the depressed part of the lid 101. Further, the flange 101a is bonded to the substrate 103. The lid 101 is bonded to the back surface of the semiconductor chip 105 by means of a binder 106. The flange 101a, and the substrate 103 are bonded together with a binder 102. For the binder 106, use is often made of material high in thermal conductivity in order to enhance thermal conductivity of the package, and for the binder 102, use is often made of resin high in adhesiveness.

For a base material of the lid 101, use is often made of copper or a copper alloy. One of the reasons for that is because copper or the copper alloy is high in thermal conductivity, and excellent in heat-release properties. As another reason for that, there can be cited the fact that copper or the copper alloy has coefficient of expansion close to that of the base material (for example, a glass-cloth epoxy substrate, glass-cloth polyimide substrate, etc.) for use in the substrate, and stress due to change in temperature can therefore be held back low. Furthermore, in consideration of corrosion resistance, adhesiveness, decorativeness, and so forth, the lid 101 is often subjected to surface treatment such as, for example, nickel plating, black treatment, and chromating.

For the constituent material of the substrate 103, use is often made of material produced by laminating together base materials prepared by impregnating a glass cloth with epoxy resin, polyimide resin, bis (maleimidetriazine) resin, and so forth, with a wiring pattern formed thereon.

FIG. 8 is a side view of the semiconductor device shown in FIG. 7. The semiconductor device is designed such that bonded parts (the flange 101a) of the lid 101 are in parallel with bonded parts of the substrate 103.

### SUMMARY

Now, if space exists on the inner side of the lid 101, as shown in FIG. 7, there is the risk that moisture making the ingress into the space undergoes vaporization due to heating upon the mounting to thereby cause a sharp rise in internal pressure, resulting in rupture of the lid 101. Accordingly, there are cases where a workpiece is dried by baking it, or through-holes are provided in order to relieve the internal pressure. Methods for making the through-holes include a method whereby a binder is applied only to portions of the flange 101a when the flange 101a of the lid 101 is bonded to the substrate 103. In such a case, the ingress of a cleaning liquid into the interior of the lid 101 occurs when cleaning is carried out for removal of flux, and so forth after soldered mounting, so that it is necessary to form the through-holes to a size not less than a certain magnitude in order to easily drain off the cleaning liquid as intruded out of the interior. For this reason, there has been the need for setting the binder so as to have a thickness on the large side to an extent.

However, if the binder is increased in thickness, there occur cases where the binder itself is broken down under a load lower than a load causing exfoliation at bonded areas when an external force is applied. As a result, there occurs deterioration in adhesion strength of the bonded parts between the lid and the substrate, which will lead to deterioration in reliability of the semiconductor device.

The invention provides a semiconductor device including a substrate, a semiconductor chip with one of surfaces thereof, facing downward, mounted on the substrate, and a lid having a depressed part for accommodating the semiconductor chip, and a flange linked with the depressed part, wherein the bottom surface of the depressed part of the lid is bonded to the other surface of the semiconductor chip, parts of the flange of the lid are bonded to the substrate, and the flange is warped arcuately against the substrate, as seen in a side view.

With the semiconductor device, the flange is warped arcuately against the substrate, as seen in the side view. Accordingly, it follows that there exist parts narrower in a spacing between the flange, and the wiring substrate as well as parts wider in a spacing therebetween. Therefore, providing the latter with through-holes, respectively, and providing the former with a binder can reduce a thickness of the binder while sufficiently securing respective sizes of the through-holes. Thereby, adhesion strength of the bonded parts between the lid and the wiring substrate is enhanced.

With the invention, it is possible to implement a semiconductor device excellent in reliability.

### BRIEF DESCRIPTION OF THE DRAWINGS

FIG. 1 is a side view broadly showing a first embodiment of a semiconductor device according to the invention;

FIG. 2 is a sectional view broadly showing the first embodiment of the semiconductor device according to the invention;

FIG. 3 is a top view broadly showing the first embodiment of the semiconductor device according to the invention;

FIG. 4 is a side view broadly showing a second embodiment of a semiconductor device according to the invention;

FIG. 5 is a sectional view broadly showing the second embodiment of the semiconductor device according to the invention;

FIG. 6 is a top view broadly showing the second embodiment of the semiconductor device according to the invention;

FIG. 7 is a sectional view showing a conventional semiconductor device; and

FIG. 8 is a side view showing the conventional semiconductor device.

### DETAILED DESCRIPTION OF THE PREFERRED EMBODIMENTS

Preferred embodiments of a semiconductor device according to the invention are described in detail hereinafter with reference to the accompanying drawings. In description of respective drawings, identical elements are denoted by like reference numerals, thereby omitting duplicated description.

### First Embodiment

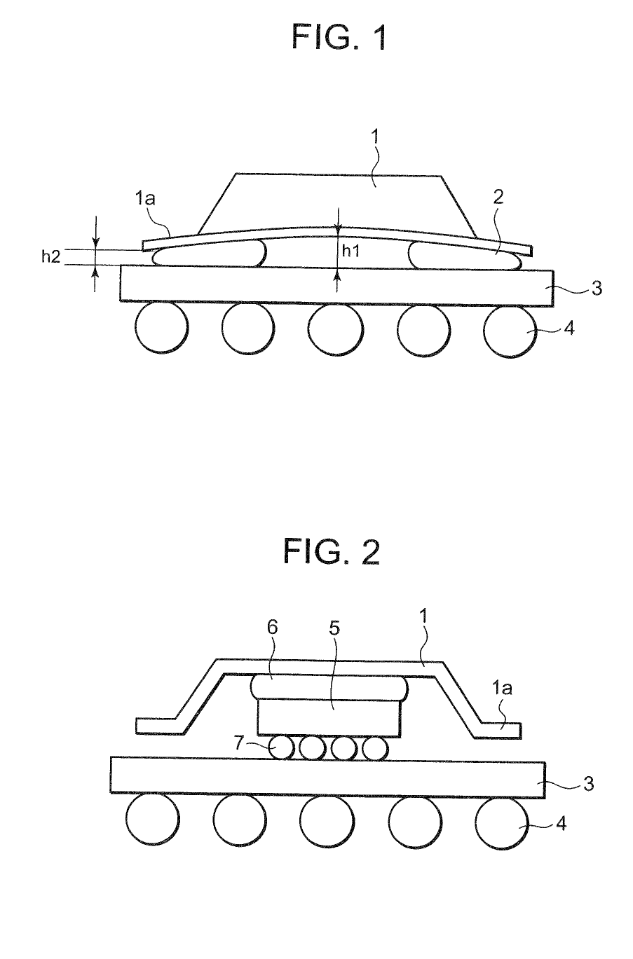

FIGS. 1 and 2 are a side view, and a sectional view, respectively, broadly showing a first embodiment of a semiconductor device according to the invention. The semiconductor device is provided with a substrate, for example, a wiring substrate 3, a semiconductor chip 5 mounted face down on the top of the wiring substrate 3, and a lid 1 having a depressed part for accommodating the semiconductor chip 5, and a flange 1a linked with the depressed part. Parts of the flange 1a (an edge thereof in the case of the present embodiment) of the lid 1 are bonded to the wiring substrate 3 by means of a binder 2. External terminals 4 are connected to the underside surface of the substrate 3.

As shown in FIG. 1, the flange 1a is warped arcuately against the substrate 3, as seen in the side view. In the present embodiment, in particular, the flange 1a is warped in such a fashion as to protrude against the substrate 3, as seen in the side view. As a result, in the side view, a spacing h1 between the center of the flange 1a, and the wiring substrate 3 is wider than a spacing h2 between the edge of the flange 1a, and the wiring substrate 3.

As shown in FIG. 2, the semiconductor chip 5 is mounted on the wiring substrate 3 by the flip chip mounting. More specifically, electrode terminals of the semiconductor chip 5 are positioned opposite to electrode terminals of the wiring substrate 3, respectively, so as to be bonded with each other through the intermediary of bumps 7 formed on the tops of the respective electrode terminals of the semiconductor chip 5. The bottom surface of the depressed part of the lid 1 is bonded to the back surface of the semiconductor chip 5.

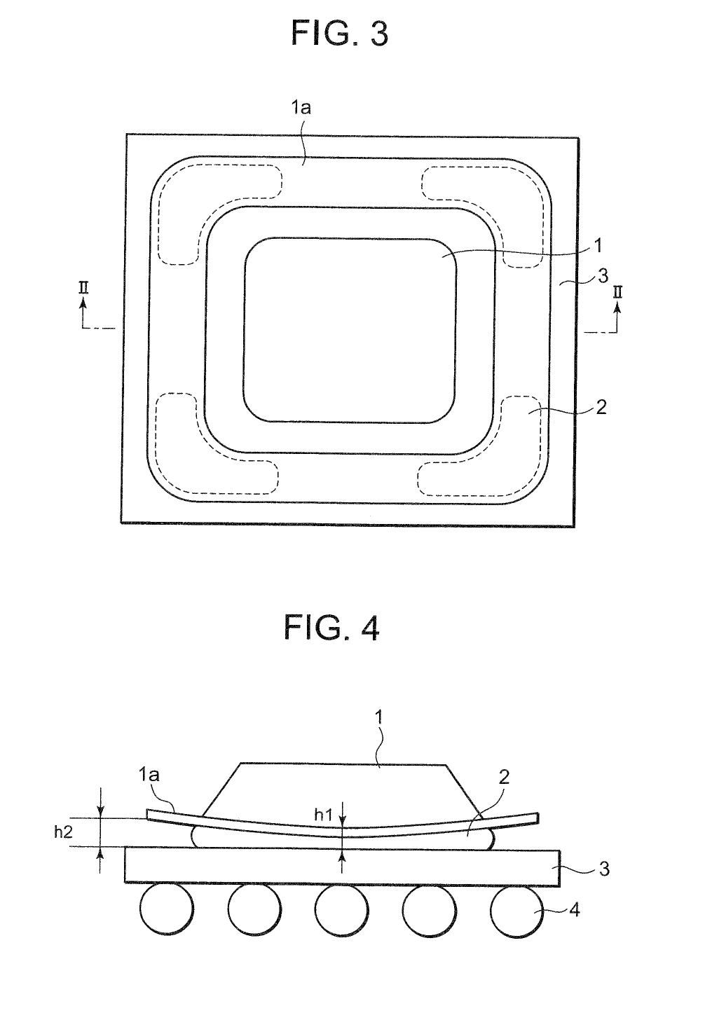

FIG. 3 is a top view broadly showing the semiconductor device shown in FIGS. 1 and 2, respectively. In the figure, the binder 2 is shown as in a see-through view. A section taken on line II-II of FIG. 3 corresponds to FIG. 2. As indicated by a broken line, the binder 2 is applied only to respective edges of the flange 1a, that is, only to respective corners of the flange 1a, and the binder 2 is not applied to the central part of the flange 1a, in the side view. The interior of the lid 1 communicates with the exterior thereof at parts where no binder is applied. In other words, those parts where no binder is applied serve as through-holes for use in draining off a cleaning liquid as intruded into the interior of the lid 1 when cleaning is carried out after soldered mounting. Further, in the case where the lid 1 is excessively heated at the time of the soldered mounting, and so forth, thereby causing an internal pressure of the lid 1 to rise, the through-holes also function as holes to let the internal pressure escape therethrough to outside.

Now, an advantageous effect of the present embodiment is described hereinafter. With the present embodiment, the flange 1a of the lid 1 is warped arcuately against the substrate 3, as seen in the side view. Accordingly, it follows that there exist parts narrower in the spacing between the flange 1a, and the wiring substrate 3 as well as parts wider in the spacing therebetween. Therefore, providing the latter with the through-holes, respectively, and providing the former with the binder 2 can reduce a thickness of the binder 2 while sufficiently securing respective sizes of the through-holes. This enhances adhesion strength of the bonded parts between the lid 1 and the wiring substrate 3; thereby, implementing the semiconductor device excellent in reliability.

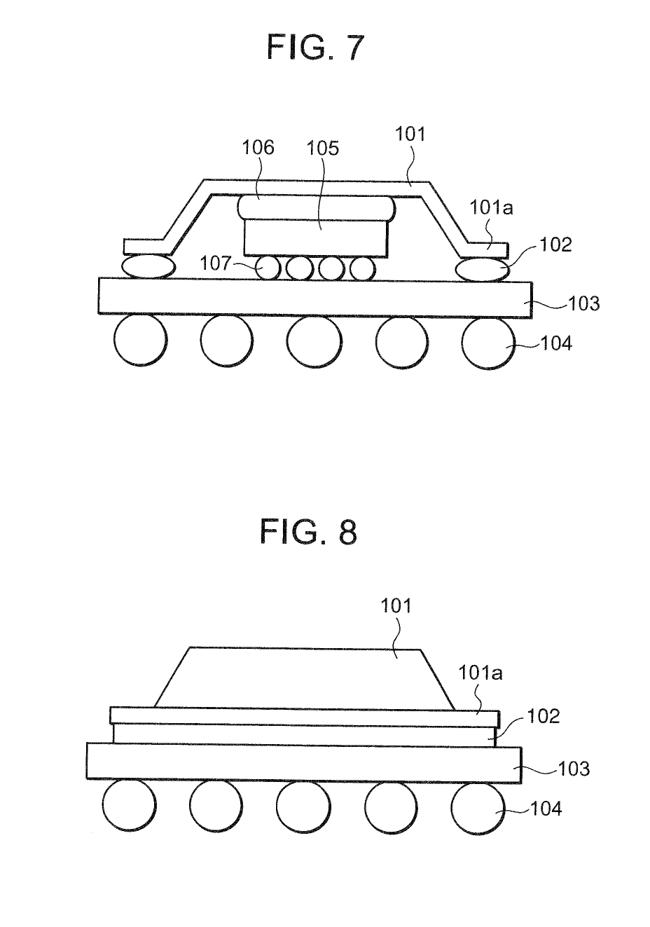

Incidentally, the conventional semiconductor device shown in FIGS. 7 and 8 has a problem in that it is under quite a few constraints in selecting the binder 102 for bonding the flange 101a of the lid 101 to the substrate 103. For example, in order that a thickness of the binder 106 bonding the semiconductor chip 105 to the lid 101 can be rendered as small as possible, it is conceivable to impose dimensional constraints on the binder 106. Thereby, the binder 106 can be rendered small in thickness, thereby enhancing, and stabilizing heat release properties; however, that will cause a problem in that there occurs an increase in the spacing at the bonded parts between the flange 101a of the lid 101, and the substrate 103. Accordingly, there arises the need for selecting material that can be formed into a shape large in thickness as the constituent material of the binder 102.

Further, taking manufacturing tolerance into account, it naturally requires that no problem ensues regardless of whether the spacing becomes the widest, or the narrowest. For this reason, it is necessary for the binder 102 for bonding the flange 101a of the lid 101 to the substrate 103 to undergo deformation as large as possible in thickness before curing so as to be capable of coping with the case of the spacing being the widest. On the other hand, in the process step of placing the lid 101 on the substrate 103 to be bonded thereto, it is necessary for the binder 102 to undergo deformation as small as possible in thickness so as to be capable of coping with the case of the spacing being the narrowest. Accordingly, the binder 102 need be a thermosetting liquid resin having a viscosity capable of holding a shape of the resin immediately after application without allowing the resin to be wet, and spread out after the application. Furthermore, the binder 102 need have properties of spreading out in such a way as to match the shape of the lid 101 when the lid 101 is placed on the substrate 103, and capable of holding its own shape including a period of curing by heating.

Because there is the need for selecting the binder 102 in consideration of circumstances described as above, the number of options becomes fewer, so that there will be no choice but to use an expensive binder. In addition, since the spacing at each of the bonded parts was wide, there resulted a corresponding increase in quantity of the binder 102 that was used, causing a problem of an increase in cost.

In contrast, with the present embodiment, there is an increase in the number of options, so that an inexpensive binder can be used as a binder 2. In addition, since the binder 2 can be applied to a small thickness, it is possible to reduce the quantity of the binder 2 that is used, so that further reduction in the cost of the binder 2 can be achieved.

### Second Embodiment

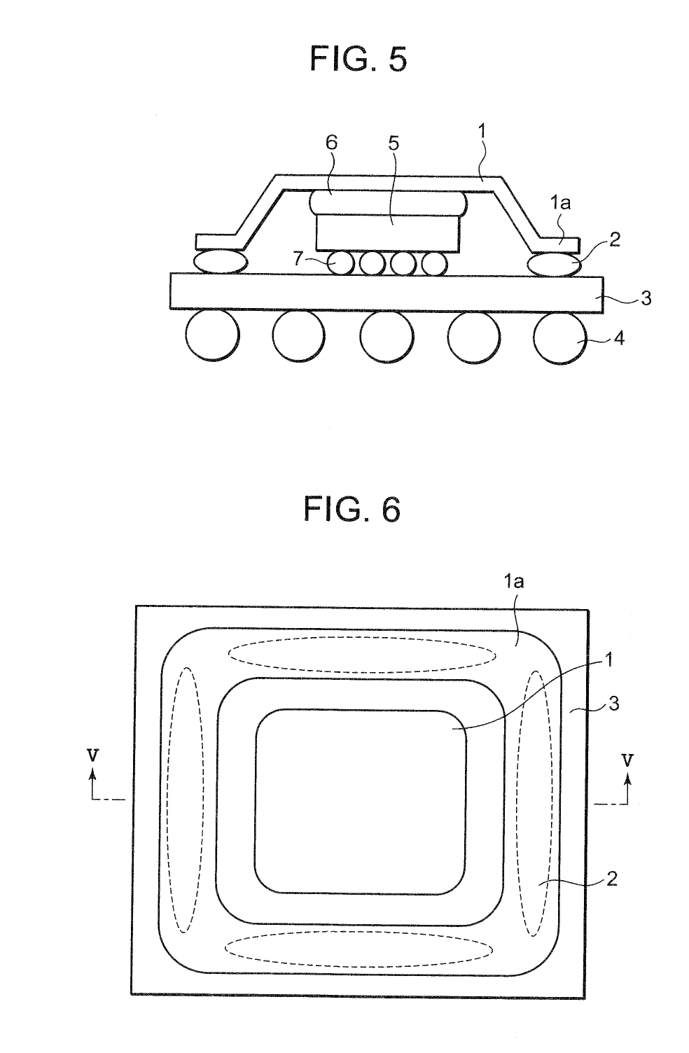

FIGS. 4 and 5 are a side view, and a sectional view, respectively, broadly showing a second embodiment of a semiconductor device according to the invention. The semiconductor device is provided with a wiring substrate 3, a semiconductor chip 5 mounted face down on the wiring substrate 3, and a lid 1 having a depressed part for accommodating the semiconductor chip 5, and a flange 1a linked with the depressed part. A part (a central part in the case of the present embodiment) of the flange 1a of the lid 1 is bonded to the wiring substrate 3 by means of the binder 2.

As shown in FIG. 4, the flange 1a is warped arcuately against the substrate 3, as seen in the side view. In the present embodiment, in particular, the flange 1a is warped in such a fashion as to be concaved against the substrate 3, as seen in the side view. As a result, in the side view, a spacing h1 between the center of the flange 1a, and the wiring substrate 3 is narrower than a spacing h2 between the edge of the flange 1a, and the wiring substrate 3.

FIG. 6 is a top view broadly showing the semiconductor device shown in FIGS. 4 and 5, respectively. In the figure, the binder 2 is shown as in a see-through view. A section taken on line V-V of FIG. 6 corresponds to FIG. 5. As indicated by a broken line, the binder 2 is applied only to the central part of the flange 1a, in the side view, and the binder 2 is not applied to respective edges of the flange 1a. The interior of the lid 1 communicates with the exterior thereof at parts where no binder is applied.

With the present embodiment, it is possible to secure space in the vicinity of respective internal corners of the lid 1. The space can be effectively utilized as a mounting region when a chip capacitor, and so forth are mounted on the wiring substrate 3. A configuration of the present embodiment, in other respects, and the effect thereof are the same as those for the first embodiment.

What is claimed is:

1. A semiconductor device comprising:
a substrate;
a semiconductor chip with one of surfaces thereof, facing downward, mounted on the substrate; and
a lid having a depressed part for accommodating the semiconductor chip, and a flange linked with the depressed part, wherein
parts of the flange of the lid are bonded to the substrate, and the flange is warped arcuately against the substrate, as seen in a side view.

2. The semiconductor device according to claim 1, wherein the flange is warped in such a fashion as to protrude against the substrate, as seen in the side view.

3. The semiconductor device according to claim 2, wherein a spacing between the center of the flange, and the substrate is wider than a spacing between an edge of the flange, and the substrate, as seen in the side view.

4. The semiconductor device according to claim 2, wherein the parts of the flange, bonded to the substrate, correspond to the edge of the flange.

5. The semiconductor device according to claim 1, wherein the flange is warped in such a fashion as to be concaved against the substrate, as seen in the side view.

6. The semiconductor device according to claim 5, wherein the spacing between the center of the flange, and the substrate is narrower than the spacing between the edge of the flange, and the substrate, as seen in the side view.

7. The semiconductor device according to claim 5, wherein part of the flange, bonded to the substrate, corresponds to the center of the flange.

8. The semiconductor device according to claim 1, wherein the bottom surface of the depressed part of the lid is bonded to the other surface of the semiconductor chip.
